(19) United States
(12) Patent Application Publication
(10) Pub. No.: US 2011/0220179 A1
(43) Pub. Date: Sep. 15, 2011

(54) ASSEMBLIES COMPRISING A THERMALLY AND DIMENSIONALLY STABLE POLYIMIDE FILM, AN ELECTRODE AND AN ABSORBER LAYER, AND METHODS RELATING THERETO

(75) Inventors: Kostantinos KOURTAKIS, Media, PA (US); Brian C. AUMAN, Pickerington, OH (US)

(73) Assignee: E. I. DU PONT DE NEMOURS AND COMPANY, Wilmington, DE (US)

(21) Appl. No.: 12/883,828

(22) Filed: Sep. 16, 2010

Related U.S. Application Data
(60) Provisional application No. 61/243,404, filed on Sep. 17, 2009.

(51) Int. Cl. H01L 31/042; H01L 31/0224

(52) U.S. Cl. 136/249; 136/256

(57) ABSTRACT

The assemblies of the present disclosure comprise an electrode, and a polyimide film. The polyimide film contains from about 40 to about 95 weight percent of a polyimide derived from at least one aromatic dianhydride component, and at least one aromatic diamine component. The aromatic dianhydride and aromatic diamine component are selected from the group consisting of rigid rod diamine, non-rigid rod diamine and combinations thereof. The mole ratio of dianhydride to diamine is 48-52:52-48 and the ratio of A:B is 20-80:80-20. A is the mole percent of rigid rod dianhydride and rigid rod diamine, and B is the mole percent of non-rigid rod dianhydride and non-rigid rod diamine. The polyimide films of the present disclosure further comprise a filler that is less than about 100 nanometers in all dimensions and is present in an amount from about 5 to about 60 weight percent of the total weight of the polyimide film.

### FIELD OF DISCLOSURE

This disclosure relates generally to assemblies comprising an electrode, and a polyimide film, where the polyimide film has: i. advantageous dielectric properties; ii. advantageous thermal and dimensional stability over a broad temperature range, even in the presence of tension or other dimensional stress; and iii. advantageous adhesion properties to metal. More specifically, the assemblies of the present disclosure are well suited for the manufacture of monolithically integrated solar cells, particularly monolithically integrated solar cells comprising a copper/indium/gallium/di-selenide (CIGS) or similar-type light absorber layer.

### BACKGROUND OF THE DISCLOSURE

To address an increasing need for alternative energy sources, there is currently a strong interest in developing light-weight, efficient photovoltaic systems (e.g., photovoltaic cells and modules). Of particular interest are photovoltaic systems having a copper/indium/gallium/di-selenide (CIGS) light absorber layer. With such systems, a high temperature deposition/annealing step is generally applied to improve light absorber layer performance. The annealing step is typically conducted during manufacture and is typically applied to an assembly, comprising a substrate, a bottom electrode and the CIGS light absorber layer. The substrate requires thermal and dimensional stability at the annealing temperature(s), and therefore conventional substrates have typically comprised metal or ceramic (conventional polymeric materials tend to lack sufficient thermal and dimensional stability, particularly at peak annealing temperatures). However, ceramics, such as glass, lack flexibility and can be heavy, bulky and subject to breakage. Metals can be less prone to such disadvantages, but metals tend to conduct electricity, which tends to also be a disadvantage, e.g., inhibits monolithic integration of CIGS photovoltaic cells. The substrate serves as a support upon which a bottom electrode (such as, a molybdenum electrode) is formed. Therefore, good adhesion between the bottom electrode and the substrate is required.

Hence, there exists a need for assemblies comprising a polymeric substrate having sufficient thermal and dimensional stability (and also sufficient dielectric properties), that the assembly: (a) can be manufactured by a relatively economical process, such as, reel-to-reel or similar-type processing, (b) enables relatively simple, straightforward monolithic integration of thin film photovoltaic cells, e.g., by reel-to-reel or similar type manufacturing processes, (c) can adequately tolerate desired deposition/annealing temperatures during fabrication of the assembly and/or (d) has good adhesion between the bottom electrode and the substrate.

### SUMMARY

The assemblies of the present disclosure comprise a polyimide film having a thickness from about 8 to about 150 microns. The polyimide film contains from about 40 to about 95 weight percent of a polyimide derived from: i. at least one aromatic dianhydride component, said aromatic dianhydride component being a member of the group consisting of rigid rod dianhydride, non-rigid rod dianhydride and combinations thereof, and ii. at least one aromatic diamine component, said aromatic diamine component being a member of the group consisting of rigid rod diamine, non-rigid rod diamine and combinations thereof. The mole ratio of dianhydride to diamine is 48-52:52-48 and the ratio of A:B is 20-80:80-20 where A is the mole percent of rigid rod dianhydride and rigid rod diamine, and B is the mole percent of non-rigid rod dianhydride and non-rigid rod diamine. The polyimide films of the present disclosure further comprise a filler, where: i. the filler has an average diameter of less than about 100, 90, 80, 70, 60, 50, 40, 30, 25 or 20 nanometers in all dimensions; and ii. the filler is present in an amount from about 5 to about 60 weight percent of the total weight of the polyimide film.

### BRIEF DESCRIPTION OF THE DRAWINGS

FIG. 1 is a sectional view of a thin-film solar cell fabricated on a polyimide film, constructed in accordance with the present disclosure.

FIG. 2 illustrates an electron micrograph picture depicting a metal-polyimide interface of the metalized polyimide of Comparative Example 1.

### DETAILED DESCRIPTION

### Definitions

“Film” is intended to mean a free-standing film or a coating on a substrate. The term “film” is used interchangeably with the term “layer” and refers to covering a desired area.

“Monolithic integration” is intended to mean integrating (either in series or in parallel) a plurality of photovoltaic cells to form a photovoltaic module, where the cells/module can be formed in a continuous fashion on a single film or substrate, e.g., a reel to reel operation.

“CIGS/CIS” is intended to mean an light absorber layer, either on its own or as part of a combination of layers, such as, in combination with an electrode, or in combination with an electrode and a polyimide film, or as part of a photovoltaic cell or module, (depending upon context) where the light absorber layer (or at least one light absorber layer) comprises: i. a copper indium gallium di-selenide composition; ii. a copper indium gallium disulfide composition; iii. a copper indium di-selenide composition; iv. a copper indium disulfide composition; or v. any element or combination of elements that could be substituted for copper, indium, gallium, di-selenide, and/or disulfide, whether presently known or developed in the future.

“Dianhydride” as used herein is intended to include precursors or derivatives thereof, which may not technically be a dianhydride but would nevertheless react with a diamine to form a polyamic acid which could in turn be converted into a polyimide.

Similarly, “diamine” as used herein is intended to include precursors or derivatives thereof, which may not technically be a diamine but would nevertheless react with a dianhydride to form a polyamic acid which could in turn be converted into a polyimide.

As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited to only those elements but may include other elements not expressly listed or inherent to such method, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, articles “a” or “an” are employed to describe elements and components of the disclosure. This is done merely for convenience and to give a general sense of the disclosure. This description should be read to include one or at least one and the singular also includes the plural unless it is obvious that it is meant otherwise.

The polyimide films used in the assemblies of the present disclosure resist shrinkage or creep (even under tension, such as, reel to reel processing) within a broad temperature range, such as, from about room temperature to temperatures in excess of 400° C., 425° C. or 450° C. In one embodiment, the support film changes in dimension by less than 1, 0.75, 0.5, or 0.25 percent when subjected to a temperature of 460° C. for 30 minutes while under a stress in a range from 7.4-8.0 MPa (megapascals). In some embodiments, the polyimide films have sufficient dimensional and thermal stability to be a viable alternative to metal or ceramic support materials. An additional advantage of the assemblies of the present disclosure is improved adherence of the polyimide film to the electrode. In some embodiments, the assemblies of the present disclosure further comprise a light absorber layer where the electrode is between the light absorber layer and the polyimide film, and the electrode is in electrical communication with the light absorber layer.

In some embodiments, the assemblies of the present disclosure can be used, for example, in thin film solar cells. When used in a CIGS/CIS application, the polyimide films of the present disclosure can provide a thermally and dimensionally stable, flexible polyimide film (support) upon which a bottom electrode (such as, a molybdenum electrode) can be sufficiently adhered to the polyimide film surface. In some embodiments, over the bottom electrode, a light absorber layer can be applied in a manufacturing step toward the formation of a CIGS/CIS photovoltaic cell. In some embodiments, the light absorber layer is a CIGS/CIS light absorber layer. In some embodiments, the polyimide film can also be coated on both sides with the electrode metal even if only one metal side is used as the electrode on which the light absorber layer is deposited.

In some embodiments, the bottom electrode is flexible. The polyimide film can be reinforced with thermally stable, inorganic: fabric, paper (e.g., mica paper), sheet, scrim or combinations thereof. In some embodiments, the polyimide film of the present disclosure has adequate electrical insulation properties to allow multiple CIGS/CIS photovoltaic cells to be monolithically integrated into a photovoltaic module. In some embodiments, the assembly further comprises a plurality of monolithically integrated CIGS/CIS photovoltaic cells. In some embodiments, the polyimide films of the present disclosure provide:
i. low surface roughness, i.e., an average surface roughness (Ra) of less than 400, 350, 300, 275 or 100 nanometers;
ii. low levels of surface defects; and/or
iii. other useful surface morphology,
   to diminish or inhibit unwanted defects, such as, electrical shorts.

In one embodiment, the polyimide films used in the assemblies of the present disclosure have an in-plane CTE in a range between (and optionally including) any two of the following: 1, 5, 10, 15, 20, 25, 30, 35 and 40 ppm/° C., where the in-plane coefficient of thermal expansion (CTE) is measured between 50° C. and 350° C. In some embodiments, the CTE within this range is further optimized to further diminish or eliminate unwanted cracking due to thermal expansion mismatch of any particular supported material selected in accordance with the present disclosure (e.g., the CIGS/CIS light absorber layer in CIGS/CIS applications). Generally, when forming the polyimide, a chemical conversion process (as opposed to a solely thermal conversion process) will provide a lower CTE polyimide film. Chemical conversion processes for converting polyamic acid into polyimide are well known and need not be further described here. The thickness of a polyimide film can also impact CTE, where thinner films tend to give a lower CTE (and thicker films, a higher CTE), and therefore, film thickness can be used to fine tune film CTE, depending upon any particular application selected. The polyimide films used in the assemblies of the present disclosure have a thickness in a range between (and optionally including) any of the following thicknesses (in microns): 8, 10, 12, 15, 20, 25, 50, 75, 100, 125 and 150 microns. Monomers and fillers within the scope of the present disclosure can also be selected or optimized to fine tune CTE within the above range. Ordinary skill and experimentation may be necessary in fine tuning any particular CTE of the polyimide films of the present disclosure, depending upon the particular application selected for the assemblies.

The polyimide films used in the assemblies of the present disclosure should have high thermal stability so the films do not substantially degrade, lose weight, have diminished mechanical properties, or give off significant volatiles, e.g., during the light absorber layer deposition and/or annealing process in a CIGS/CIS application of the present disclosure. In a CIGS/CIS application, in one embodiment the polyimide film should be thin enough to not add excessive weight to the photovoltaic module, but thick enough to provide high electrical insulation at operating voltages, which in some cases may reach 400, 500, 750 or 1000 volts or more.

The polyimide films used in the assemblies of the present disclosure should have good adhesion to the bottom electrode. In accordance with the present disclosure, a filler is added to the polyimide film to improve adhesion of the polyimide film to metal. In some embodiments, the filler increases the storage modulus above the glass transition temperature (Tg) of the polyimide film. The addition of filler typically allows for the retention of mechanical properties at high temperatures and can improve handling characteristics. The fillers of the present disclosure:
1. have a average diameter of less than (as a numerical average) 100 nanometers (and in some embodiments, less than 80, 75, 65, 60, 55, 50, 45, 40, 35, 30, 25, or 20 nanometers) in all dimensions; and
2. is present in an amount between and optionally including any two of the following percentages: 5, 10, 15, 20, 25, 30, 35, 40, 45, 50, 55, and 60 weight percent, based upon the total weight of the polyimide film.

Fillers of the present disclosure are nano fillers. Suitable fillers are generally stable at temperatures above 450° C., and in some embodiments do not significantly decrease the electrical insulation properties of the polyimide film. The fillers of the present disclosure can be any shape, including spherical and oblong. In one embodiment, the filler is relatively uniform in size and is substantially non-aggregated. The filler can be hollow, porous, or solid.

In one embodiment, the filler of the present disclosure is an inorganic oxide, such as but not limited to silicon oxide (silica), titanium oxide, aluminum oxide, zirconium oxide, and binary, ternary, quaternary and higher order composite oxides of one or more cations selected from silicon, titanium, aluminum and zirconium. More than one type of filler may be used in any combination. In one embodiment, filler composites (e.g. single or multiple core/shell structures) can be used, in which one oxide encapsulates another oxide in one particle.

In some embodiments, the filler is an inorganic oxide, and the polyimide film has (i) a Tg greater than 300° C. and (ii) a dielectric strength greater than 500 volts per 25.4 microns. In some embodiments, at least 70, 80, 90, 95, 97, 98, 99 or 100 weight percent of the filler comprises an inorganic oxide. In one embodiment, fillers of the present disclosure are produced from sols of silicon oxides (e.g., colloidal dispersions of solid nanosilica in liquid media), especially sols of amorphous, semi-crystalline, and/or crystalline nanosilica. Such sols can be prepared by a variety of techniques and in a variety of forms, which include hydrosols (where water serves as the liquid medium), organosols (where organic liquids serve as the liquid medium), and mixed sols (where the liquid medium comprises both water and an organic liquid), see for example, U.S. Pat. Nos. 4,522,958; and 5,648,407. In one embodiment, the filler is suspended in a polar, aprotic solvent, such as, DMAC or other solvent compatible with polyamic acid. In another embodiment, solid nanosilica fillers can be commercially obtained as colloidal dispersions or sols dispersed in polar aprotic solvents, such as for example Nissan DMAC-ST, a solid silica colloid in dimethylacetamide containing<0.5 percent water, median silica particle diameter d₅₀ of about 16 nm, 20-21 wt % silica, available from Nissan Chemicals America Corporation, Houston, Tex., USA.

Porous nanosilica fillers can be used alone, or as a mixture with other nano fillers to form the polyimide composite. A porous nano filler comprises at least one portion of a lower density material, such as air, and in one embodiment can be a shell of silica (e.g., a hollow nanosilica particle). Methods for producing hollow nanosilica particles are known, for example, as described in JP-A-2001/233611 and JP-A-2002/79616.

In some embodiments, the filler is coated with a coupling agent. In some embodiments, the filler is coated with an aminosilane coupling agent. In some embodiments, the filler is coated with a dispersant. In some embodiments, the filler is coated with a combination of a coupling agent and a dispersant. Alternatively, the coupling agent, dispersant or a combination thereof can be incorporated directly into the polyimide film and not necessarily coated onto the filler.

In some embodiments, a filtering system is used to ensure that the final polyimide film will not contain discontinuous domains greater than the desired maximum filler size. In some embodiments, the filler is subjected to intense dispersion energy, such as agitation and/or high shear mixing or media milling or other dispersion techniques, including the use of dispersing agents, when incorporated into the polyimide film (or incorporated into a film precursor) to inhibit unwanted agglomeration above the desired maximum filler size.

Generally speaking, film smoothness is desirable, since surface roughness: i. can interfere with the functionality of the layer or layers deposited on top, ii. can increase the probability of electrical or mechanical defects, and iii. can diminish property uniformity along the film. In one embodiment, the filler (and any other discontinuous domains) are sufficiently dispersed during film formation, such that the filler (and any other discontinuous domains) are sufficiently between the surfaces of the film upon film formation to provide a final polyimide film having an average surface roughness (Ra) of less than 400, 350, 300, 275 or 100 nanometers. Surface roughness as provided herein can be determined by optical surface profilometry to provide Ra values, such as, by measuring on a Veeco Wyco NT 1000 Series brand surface roughness instrument in VSI mode at 25.4× or 51.2× utilizing Wyco Vision 32 brand analytical software.

In some embodiments, the filler is chosen so that it does not itself degrade or produce off-gasses at the desired processing temperatures. Likewise in some embodiments, the filler is chosen so that it does not contribute to degradation of the polymer.

The polyimide base polymers of the present disclosure are derived from the polymerization reaction of certain aromatic dianhydrides with certain aromatic diamines to provide a polymeric backbone structure that comprises both rigid rod portions and non-rigid rod portions. The rigid rod portions arise from the polymerization of aromatic rigid rod monomers into the polyimide, and the non-rigid rod portions arise from the polymerization of non-rigid rod aromatic monomers into the polyimide. Aromatic rigid rod monomers give a co-linear (about 180°) configuration to the polymer backbone, and therefore relatively little movement capability, when polymerized into a polyimide.

Examples of aromatic rigid rod diamine monomers are:
1,4-diaminobenzene (PPD),
4,4′-diaminobiphenyl,
2,2′-bis(trifluoromethyl) 4,4′-diaminobiphenyl (TFMB),
1,4-naphthalenediamine,
1,5-naphthalenediamine,
4,4″-diamino terphenyl,
4,4′-diamino benzanilide
4,4′-diaminophenyl benzoate,
3,3′-dimethyl-4,4′-diaminobiphenyl, and the like.
   Examples of aromatic rigid rod dianhydride monomers are:
      pyromellitic dianhydride (PMDA),
      2,3,6,7-Naphthalenetetracarboxylic dianhydride, and
      3,3′,4,4′-biphenyl tetracarboxylic dianhydride (BPDA).
         Monomers having a freedom of rotational movement or bending (once polymerized into a polyimide) substantially equal to or less than the above examples (of rigid rod diamines and rigid rod dianhydrides) are intended to be deemed rigid rod monomers for purposes of this disclosure.

Non-rigid rod monomers for purposes of this disclosure are intended to mean aromatic monomers capable of polymerizing into a polyimide backbone structure having substantially greater freedom of movement compared to the rigid rod monomers described and exemplified above. The non rigid rod monomers, when polymerized into a polyimide, provide a backbone structure having a bend or otherwise are not co-linear along the polyimide backbone they create (e.g., are not about 180°). Examples of non-rigid rod monomers in accordance with the present disclosure include any diamine and any dianhydride capable of providing a rotational or bending bridging group along the polyimide backbone. Examples of rotational or bending bridging groups include —O—, —S—, —SO₂—, —C(O)—, —C(CH₃)₂—, —C(CF₃)₂—, and —C(R,R′)— where R and R′ are the same or different and are any organic group capable of bonding to a carbon.

Examples of non-rigid rod diamines include: 4,4′-diaminodiphenyl ether (“ODA”), 2,2-bis-(4-aminophenyl) propane, 1,3-diaminobenzene (MPD), 4,4′-diaminobenzophenone, 4,4′-diaminodiphenylmethane, 4,4′-diaminodiphenyl sulfide, 4,4′-diaminodiphenyl sulfone, 3,3′-diaminodiphenyl sulfone, bis-(4-(4-aminophenoxy)phenyl sulfone (BAPS), 4,4′-bis-(aminophenoxy)biphenyl (BAPB), 3,4′-diaminodiphenyl ether, 4,4′-diaminobenzophenone, 4,4′-isopropylidenedianiline, 2,2′-bis-(3-aminophenyl)propane, N,N-bis-(4-aminophenyl)-n-butylamine, N,N-bis-(4-aminophenyl) methylamine, m-amino benzoyl-p-amino anilide, 4-aminophenyl-3-aminobenzoate, N,N-bis-(4-aminophenyl) aniline, 2,4-diaminotoluene, 2,5-diaminotoluene, 2,6-diaminotoluene, 2,4-diamine-5-chlorotoluene, 2,4-diamino-6-chlorotoluene, 2,4-bis-(beta-amino-t-butyl) toluene, bis-(p-beta-amino-t-butyl phenyl)ether, p-bis-2-(2-methyl-4-aminopentyl) benzene, m-xylylene diamine, p-xylylene diamine. 1,2-bis-(4-aminophenoxy)benzene, 1,3-bis-(4-aminophenoxy) benzene, 1,2-bis-(3-aminophenoxy)benzene, 1,3-bis-(3-aminophenoxy) benzene, 1-(4-aminophenoxy)-3-(3-aminophenoxy) benzene, 1,4-bis-(4-aminophenoxy) benzene, 1,4-bis-(3-aminophenoxy) benzene, 1-(4-aminophenoxy)-4-(3-aminophenoxy) benzene, 2,2-bis-(4-[4-aminophenoxy]phenyl) propane (BAPP), 2,2′-bis-(4-aminophenyl)-hexafluoro propane (6F diamine), 2,2′-bis-(4-phenoxy aniline) isopropylidene, 4,4′-diamino-2,2′-trifluoromethyl diphenyloxide, 3,3′-diamino-5,5′-trifluoromethyl diphenyloxide, 4,4′-trifluoromethyl-2,2′-diaminobiphenyl, 2,4,6-trimethyl-1,3-diaminobenzene, 4,4′-oxy-bis-[2-trifluoromethyl)benzene amine] (1,2,4-OBABTF), 4,4′-oxy-bis-[3-trifluoromethyl)benzene amine], 4,4′-thio-bis-[(2-trifluoromethyl)benzene-amine], 4,4′-thiobis[(3-trifluoromethyl)benzene amine], 4,4′-sulfoxl-bis-[(2-trifluoromethyl)benzene amine, 4,4′-sulfoxyl-bis-[(3-trifluoromethyl)benzene amine], and 4,4′-keto-bis-[(2-trifluoromethyl)benzene amine].

Examples of non-rigid rod aromatic dianhydrides include 2,2′,3,3′-benzophenone tetracarboxylic dianhydride, 2,3,3′,4′-benzophenone tetracarboxylic dianhydride, 3,3′,4,4′-benzophenone tetracarboxylic dianhydride (BTDA), 2,2′,3,3′-biphenyl tetracarboxylic dianhydride, 2,3,3′,4′-biphenyl tetracarboxylic dianhydride, 4,4′-thio-diphthalic anhydride, bis(3,4-dicarboxyphenyl) sulfone dianhydride (DSDA), bis(3,4-dicarboxyphenyl) sulfoxide dianhydride, 4,4′-oxydiphthalic anhydride (ODPA), bis(3,4-dicarboxyphenyl) thio ether dianhydride, bisphenol A dianhydride (BPADA), bisphenol S dianhydride, 2,2-bis-(3,4-dicarboxyphenyl) 1,1,1,3,3,3,-hexafluoropropane dianhydride (6FDA), 5,5-[2,2,2]-trifluoro-1-(trifluoromethyl)ethylidene, bis-1,3-isobenzofurandione, bis(3,4-dicarboxyphenyl) methane dianhydride, cyclopentadienyl tetracarboxylic acid dianhydride, ethylene tetracarboxylic acid dianhydride, 2,2-bis(3,4-dicarboxyphenyl) propane dianhydride.

In one embodiment, the mole ratio of rigid rod monomers to non-rigid rod monomers can be 20-80:80-20 and in alternative embodiments can be any sub-range within that broad ratio (e.g., 20-80 includes any range between and optionally including 20, 25, 30, 35, 40, 45, 50, 55, 60, 65, 70, 75 and 80, and 80-20 includes any range between and optionally including 80, 75, 70, 65, 60, 55, 45, 40, 35, 30, and 25).

In one embodiment, the polyimide of the present disclosure is derived from substantially equal molar amounts of 4,4′-diaminodiphenyl ether (ODA) non-rigid rod monomer, and pyromellitic dianhydride (PMDA), rigid rod monomer. In another embodiment, the polyimide is a block copolymer. A block copolymer is a polymer in which there are sequences of substantially one dianhydride/diamine combination along the polymer backbone as opposed to a completely random distribution of monomer sequences. Typically this is achieved by sequential addition of different monomers during the polyamic acid preparation. In another embodiment, the polyimide is a block copolymer of ODA and 1,4-diaminobenzene (PPD) with PMDA, where up to 40 mole percent of the blocks can have PPD as the diamine component and at least 60 mole percent of the block have ODA as the diamine component (both blocks would have PMDA as the dianhydride component). In yet another embodiment, the polyimide is a random or block copolymer of ODA and PPD with PMDA and 3,3′,4,4′-biphenyl tetracarboxylic dianhydride (BPDA). In yet another embodiment, the polyimide is a block copolymer consisting of substantially rigid blocks (PMDA reacted with PPD) and substantially more flexible blocks (PMDA reacted with ODA). In another embodiment, the block copolymer comprises from 10 to 40 mole % blocks of PMDA and PPD and from 60 to 90 mole % blocks of PMDA and ODA.

Polyimide films of the present disclosure can be made by methods well known in the art. In some embodiments, the polyimide film can be produced by combining the above monomers together with a solvent to form a polyamic acid (also called a polyamide acid solution). The dianhydride and diamine components are typically combined in a molar ratio of aromatic dianhydride component to aromatic diamine component of from 0.90 to 1.10. Molecular weight can be adjusted by adjusting the molar ratio of the dianhydride and diamine components.

Chemical or thermal conversion can be used in the practice of the present disclosure. In instances where chemical conversion is used, a polyamic acid casting solution is derived from the polyamic acid solution. In one embodiment, the polyamic acid casting solution comprises the polyamic acid solution combined with conversion chemicals, such as: (i) one or more dehydrating agents, such as, aliphatic acid anhydrides (acetic anhydride, etc.) and aromatic acid anhydrides; and (ii) one or more catalysts, such as, aliphatic tertiary amines (triethylamine, etc.), aromatic tertiary amines (dimethylaniline, etc) and heterocyclic tertiary amines (pyridine, picoline, isoquinoilne, etc). The anhydride dehydrating material is often used in a molar excess of the amount of amide acid groups in the copolyamic acid. The amount of acetic anhydride used is typically about 2.0-3.0 moles per equivalent of amide acid. Generally, a comparable amount of tertiary amine catalyst is used.

In one embodiment, the polyamic acid is dissolved in an organic solvent at a concentration from about 5 weight percent up to and including 90 weight percent. In one embodiment, the polyamic acid is dissolved in an organic solvent at a concentration of about 5, 10, 15, 20, 25, 30, 35, 40, 45, 50, 55, 60, 65, 70, 75, 80, 85, or 90 weight percent. Examples of suitable solvents include: formamide solvents (N,N-dimethylformamide, N,N-diethylformamide, etc.), acetamide solvents (N,N-dimethylacetamide, N,N-diethylacetamide, etc.), pyrrolidone solvents (N-methyl-2-pyrrolidone, N-vinyl-2-pyrrolidone, etc.), phenol solvents (phenol, o-, m- or p-cresol, xylenol, halogenated phenols, catechol, etc.), hexamethylphosphoramide and gamma-butyrolactone. It is desirable to use one of these solvents or mixtures thereof. It is also possible to use combinations of these solvents with aromatic hydrocarbons such as xylene and toluene, or ether containing solvents like diglyme, propylene glycol methyl ether, propylene glycol, methyl ether acetate, tetrahydrofuran, and the like.

In one embodiment, the prepolymer can be prepared and combined with the filler (dispersion or nanocoloid thereof) using numerous variations to form the polyimide film of this invention. “Prepolymer” is intended to mean a lower molecular weight polymer, typically made with a slight stoichiometric excess (about 2%) of diamine monomer (or excess dianhydride monomer). Increasing the molecular weight (and solution viscosity) of the prepolymer can be accomplished by adding incremental amounts of additional dianhydride (or additional diamine, in the case where the dianhydride monomer is originally in excess in the prepolymer) in order to approach a 1:1 stoichiometric ratio of dianhydride to diamine.

Useful methods for producing polyimide film prepolymer in accordance with the present disclosure can be found in U.S. Pat. No. 5,166,308 to Kreuz, et al. Numerous variations are also possible, such as: (a) a method wherein the diamine components and dianhydride components are preliminarily mixed together and then the mixture is added in portions to a solvent while stirring, (b) a method wherein a solvent is added to a stirring mixture of diamine and dianhydride components (contrary to (a) above), (c) a method wherein diamines are exclusively dissolved in a solvent and then dianhydrides are added thereto at such a ratio as allowing to control the reaction rate, (d) a method wherein the dianhydride components are exclusively dissolved in a solvent and then amine components are added thereto at such a ratio to allow control of the reaction rate, (e) a method wherein the diamine components and the dianhydride components are separately dissolved in solvents and then these solutions are mixed in a reactor, (f) a method wherein the polyamic acid with excessive amine component and another polyamic acid with excessive dianhydride component are preliminarily formed and then reacted with each other in a reactor, particularly in such a way as to create a non-random or block copolymer, (g) a method wherein a specific portion of the amine components and the dianhydride components are first reacted and then the residual diamine components are reacted, or vice versa, (h) a method wherein the conversion chemicals are mixed with the polyamic acid to form a polyamic acid casting solution and then cast to form a gel film, (i) a method wherein the components are added in part or in whole in any order to either part or whole of the solvent, also where part or all of any component can be added as a solution in part or all of the solvent, (j) a method of first reacting one of the dianhydride components with one of the diamine components giving a first polyamic acid, hen reacting the other dianhydride component with the other amine component to give a second polyamic acid, and then combining the amic acids in any one of a number of ways prior to film formation.

The filler (dispersion or nanocolloid thereof) can be added at several points in the polyimide film preparation. In one embodiment, the nanocolloid is incorporated into a prepolymer to yield a Brookfield solution viscosity in the range of about 50-100 poise at 25° C. In an alternative embodiment, the nanocolloid can be combined with the monomers directly, and in this case, polymerization occurs with the nanocolloid present during the reaction. The monomers may have an excess of either monomer (diamine or dianhydride) during this “in situ” polymerization. The monomers may also be added in a 1:1 ratio. In the case where the monomers are added with either the amine (case i) or the dianhydride (case ii) in excess, increasing the molecular weight (and solution viscosity) can be accomplished, if necessary, by adding incremental amounts of additional dianhydride (case i) or diamine (case ii) to approach the 1:1 stoichiometric ratio of dianhydride to amine.

The polyamic acid casting solution can then be cast or applied onto a support, such as an endless belt or rotating drum, to give a film. Next, the solvent-containing film can be converted into a self-supporting film by baking at an appropriate temperature (thermal curing) together with conversion chemical reactants (chemical curing). The film can then be separated from the support, oriented such as by tentering, with continued thermal and chemical curing to provide a polyimide film.

An alkoxy silane coupling agent can be added during the process by pretreating the nanocolloid prior to formulation. Alkoxysilane coupling agents can also be added during the “in situ” polymerization by combining the nanocolloids and monomers with the alkoxysilane.

In some cases, the dianhydride can be contacted with the nanocolloid. While not intending to be bound to any particular theory or hypothesis, it is believed such contact between the dianhydride and the nanocolloid can functionalize the nanocolloid with the dianhydride prior to further reaction with the monomers or prepolymer. Ultimately, a filled polyamic acid composition is generally cast into a film, which is subjected to drying and curing (chemical and/or thermal curing) to form a filled polyimide free-standing or non free-standing film. Any conventional or non-conventional method of manufacturing filled polyimide films can be used in accordance with the present disclosure. The manufacture of filled polyimide films in general is well known and need not be further described here. In one embodiment, the polyimide used in an assembly of the present disclosure has a high glass transition temperature (Tg) of greater than 300, 310, 320, 330, 340, 350, 360, 370 380, 390 or 400° C. A high Tg generally helps maintain mechanical properties, such as storage modulus, at high temperatures.

In some embodiments, the crystallinity and amount of crosslinking of the polyimide film can aid in storage modulus retention. In one embodiment, the polyimide film storage modulus (as measured by dynamic mechanical analysis, DMA) at 480° C. is at least: 400, 450, 500, 550, 600, 650, 700, 750, 800, 850, 900, 950, 1000, 1100, 1200, 1300, 1400, 1500, 1600, 1800, 2000, 2200, 2400, 2600, 2800, 3000, 3500, 4000, 4500, or 5000 MPa.

In some embodiments, the polyimide film used in an assembly of the present disclosure has an isothermal weight loss of less than 2, 1.5, 1, 0.75, 0.5 or 0.3 percent at 500° C. over about 30 minutes in an inert environment, such as, in a vacuum or under nitrogen or other inert gas. Polyimides used in the assemblies of the present disclosure have high dielectric strength, generally higher than many common inorganic insulators. In some embodiments, polyimides used in the assemblies of the present disclosure have a breakdown voltage equal to or greater than 10 V/micrometer.

The polyimide film can further comprise any one of a number of additives, such as processing aids (e.g., oligomers), antioxidants, light stabilizers, flame retardant additives, anti-static agents, heat stabilizers, ultraviolet absorbing agents, fillers or various reinforcing agents.

In some embodiments, electrically insulating fillers may be added to modify the electrical properties of the polyimide film. In some embodiments, it is important that the polyimide film be free of pinholes or other defects (foreign particles, gels, filler agglomerates or other contaminates) that could adversely impact the electrical integrity and dielectric strength of the polyimide film, and this can generally be addressed by filtering. Such filtering can be done at any stage of the film manufacture, such as, filtering solvated filler before or after it is added to one or more monomers and/or filtering the polyamic acid, particularly when the polyamic acid is at low viscosity, or otherwise, filtering at any step in the manufacturing process that allows for filtering. In one embodiment, such filtering is conducted at the minimum suitable filter pore size or at a level just above the largest dimension of the selected filler material.

A single layer polyimide film can be made thicker in an attempt to decrease the effect of defects caused by unwanted (or undesirably large) discontinuous phase material within the film. Alternatively, multiple layers of polyimide may be used to diminish the harm of any particular defect (unwanted discontinuous phase material of a size capable of harming desired properties) in any particular layer, and generally speaking, such multilayers will have fewer defects in performance compared to a single polyimide layer of the same thickness. Using multiple layers of polyimide films can diminish or eliminate the occurrence of defects that may span the total thickness of the film, because the likelihood of having defects that overlap in each of the individual layers tends to be extremely small. Therefore, a defect in any one of the layers is much less likely to cause an electrical or other type failure through the entire thickness of the film. In some embodiments, the polyimide film comprises two or more layers. In some embodiments, the polyimide layers are the same. In some embodiments, the polyimide layers are different. In some embodiments, the polyimide layers independently may comprise a thermally stable filler, reinforcing fabric, inorganic paper, sheet, scrim or combinations thereof. Optionally, 0-55 weight percent of the polyimide film also includes other ingredients to modify properties as desired or required for any particular application.

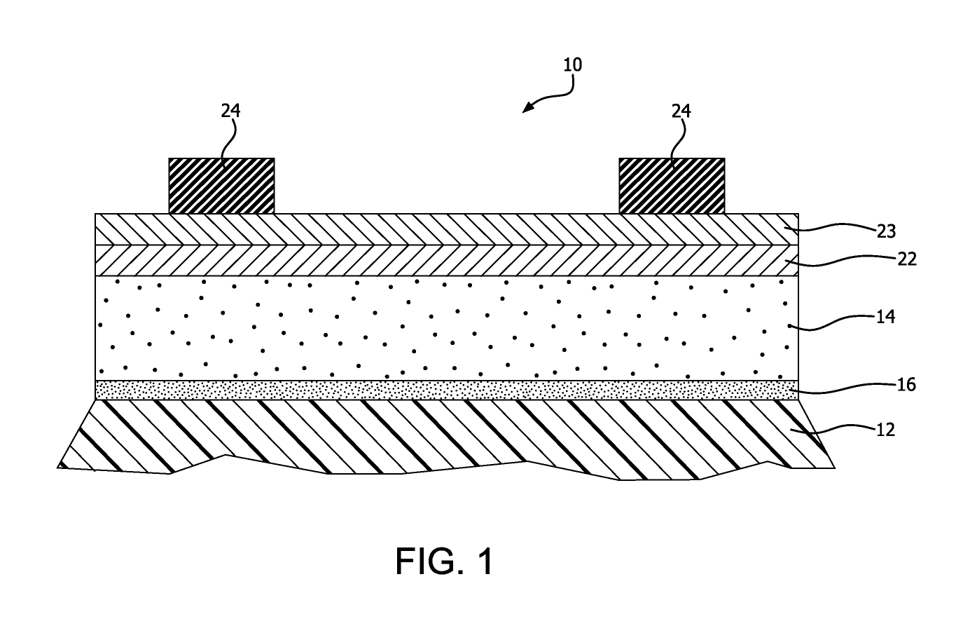

Referring now to FIG. 1, an embodiment of the present disclosure is illustrated as a thin-film solar cell, indicated generally at 10. The thin-film solar cell 10 includes a flexible polyimide film substrate 12 containing nanoscopic inorganic oxide filler as described and discussed above. A bottom electrode 16 (comprising molybdenum, for example) is applied onto the flexible polyimide film substrate 12, such as, by sputtering, evaporation deposition or the like. A semiconductor light absorber layer 14 (comprising Cu(In, Ga)Se₂, for example) is deposited over the bottom electrode 16. The deposition of the semiconductor light absorber layer 14 onto the bottom electrode 16 and the flexible polyimide film substrate 12 can be by any of a variety of conventional or non-conventional techniques including, but not limited to, casting, laminating, co evaporation, sputtering, physical vapor deposition, chemical vapor deposition, and the like. Deposition processes for semiconductor light absorber layer 14 are well known and need not be further described here (examples of such deposition processes are discussed and described in U.S. Pat. No. 5,436,204 and U.S. Pat. No. 5,441,897).

An optional adhesion layer or adhesion promoter (not shown) can be used to increase adhesion between any of the above described layers. In one embodiment, the flexible polyimide film substrate 12 is thin and flexible, i.e., approximately 8 microns to approximately 150 microns, in order that the thin-film solar cell 10 is lightweight, or the flexible polyimide film substrate 12 can be thick and rigid to improve handling of the thin-film solar cell 10.

To complete the construction of the thin-film solar cell 10 in this particular embodiment, additional optional layers can be applied. For example, the CIGS light absorber layer 14 can be paired (e.g., covered) with a II/VI film 22 to form a photoactive heterojunction. In some embodiments, the II/VI film 22 is constructed from cadmium sulfide (CdS). Alternatively, the II/VI films 22 can be constructed from other materials including, but not limited to, cadmium zinc sulfide (CdZnS) and/or zinc selenide (ZnSe) is also within the scope of the present disclosure.

A transparent conducting oxide (TCO) layer 23 for collection of current is applied to the II/VI film. Preferably, the transparent conducting oxide layer 23 is constructed from zinc oxide (ZnO), although constructing the transparent conducting oxide (“TCO”) layer 23 from other materials is also within the scope of the present disclosure.

A suitable grid contact 24 or other suitable collector is deposited on the upper surface of the TCO layer 23 when forming a stand-alone thin-film solar cell 10. The grid contact 24 can be formed from various materials but should have high electrical conductivity and form a good ohmic contact with the underlying TCO layer 23. In some embodiments, the grid contact 24 is constructed from a metal material, although constructing the grid contact 24 from other materials including, but not limited to, aluminum, indium, chromium, or molybdenum, with an additional conductive metal overlayment, such as copper, silver, or nickel is within the scope of the present disclosure.

In some embodiments, one or more anti-reflective coatings (not shown) can be applied to the exposed surfaces of the grid contact 24 and the exposed surfaces of transparent conducting oxide layer 23 that are not in contact with the grid contacts. In another embodiment, an anti-reflective coating can be applied to only the exposed surfaces of transparent conducting oxide layer 23 that are not in contact with the grid contacts. The anti-reflective coating improves the collection of incident light by the thin-film solar cell 10. As understood by a person skilled in the art, any suitable anti-reflective coating is within the scope of the present disclosure.

The invention will be further described in the following examples, which are not intended to limit the scope of the invention described in the claims.

### EXAMPLES

### Example 1

### Prophetic

Molybdenum layer (approximately 500 nm)+Nanosilica Filled Block Co-Polymer Polyimide (PMDA:ODA) 0.3 (PMDA:PPD) 0.7, where the nanosilica loading in the polyimide is 15.3 wt % (0.10 volume fraction nanosilica in the polyimide).

The prepolymer is prepared in a 100 ml, three-neck round bottom flask under a gentle nitrogen gas purge. 3.84 grams of PPD (paraphenylenediamine) is combined with 113.0 grams of anhydrous DMAC (dimethyl acetamide) and stirred, with gentle heating at 40° C. for approximately 20 minutes. 7.41 grams of PMDA (pyromellitic dianhydride, Aldrich 412287, Allentown, Pa.) is then added to this mixture to create the first block, which is stirred with gentle heating (35-40° C.) for approximately 2 hours. The mixture is allowed to cool to room temperature. 16.6 grams grams of ODA (4,4′-oxydianiline) is then added along with an additional 83.5 grams of anhydrous DMAC. This mixture is allowed to dissolve in to the formulation for about 5 minutes. An ice water bath is then used to control the temperature during the subsequent PMDA addition. 16.6 g PMDA is slowly added to this mixture while monitoring the temperature and maintaining the temperature at 30-35 g. An additional 20.5 grams of anhydrous DMAC is added to the formulation and the reaction is allowed to stir with gentle heat (30-35 degrees) for 90 minutes. The mixture is allowed to stir at room temperature for approximately 18 hours. The final prepolymer contains 18 wt % polyamic acid and has an anhydride:amine molar ratio of 0.95.

In a 250 ml round bottom flask, 109.0 grams of the prepolymer described above is combined with 11.0 gram of a 29.03 wt % SiO2 colloid in DMAC. The nanosilica colloid in DMAC is DMAC-ST (20 wt nanosilica in DMAC, Nissan Chemicals, Houston Tex.). The material is placed on a rotovap and the DMAC solvent is removed until a concentration of approximately 29 wt % is achieved (wt % of nanosilica in colloid). The percentage of nanosilica in the colloid can be determined by gravimetry.

The mixture of prepolymer and nanosilica is allowed to stir for two hours at room temperature.

The formulation is filtered through 45 micron filter media. Approximately 85 grams of material is separated into a small container for the subsequent steps.

In a separate container, a 6 wt % solution of pyromellitic anhydride (PMDA) is prepared by combining 0.9 g of PMDA (Aldrich 412287, Allentown, Pa.) and 15 ml of DMAC.

Increasing molecular weight of the prepolymer/nanosilica mixture can be accomplished by adding small incremental amounts of additional dianhydride in order to approach stoichiometric equivalent of dianhydride to diamine. Hence, the PMDA solution is slowly added to the prepolymer slurry to achieve a final viscosity of approximately 955 poise, as measured by a Brookfield DV-E viscometer with a #5 spindle. The formulation is stored overnight at 0° C. to allow it to degas.

The formulation is cast using a 25 mil doctor blade onto a surface of a glass plate to form a 3″×4″ film. The cast film and the glass plate are then soaked in a solution containing 110 ml of 3-picoline (beta picoline, Aldrich, 242845) and 110 ml of acetic anhydride (Aldrich, 98%, P42053).

The film is subsequently lifted off of the glass surface, and is mounted on a 3″×4″ pin frame.

The mounted film is placed in a furnace (Thermolyne, F6000 box furnace). The furnace is purged with nitrogen and heated according to the following temperature protocol:

40° C. to 125° C. (ramp at 4° C./min)

125° C. to 125° C. (soak 30 min)

125° C. to 250° C. (ramp at 4° C./min)

250° C. (soak 30 min)

250° C. to 400° C. (ramp at 5° C./min)

400° C. (soak 20 min)

A molybdenum layer (about 500 nm thick) is sputtered onto both sides of the polyimide layer. A Denton Discovery 20LL sputtering chamber is used for the deposition of molybdenum onto both sides of the polyimide film described above. The device is equipped with three 3″ Angstrom Sciences sputtering guns and a 3″×¼″ molybdenum (K. J. Lesker, 2×S.C.I., 99.95% & 99.99%) target. Ultra high purity grade Ar gas (GT&S Inc.) is used for the sputtering experiments.

The film samples are attached to a platter using Kapton® tape then inserted into a load lock (LL) chamber. The LL chamber is pumped down to a suitable pressure, and subsequently an isolation valve is opened and the sample is transferred into the main chamber. It is rotated while held in a horizontal orientation during the operation.

All sputter guns are positioned six inches distance from the samples, and approximately 3 inches from the outside circumference. In addition, the sputter gun face is at an angle of 20 degrees from vertical and aimed toward the axis of the sample platter.

20 sccm (standard cubic centimeters per minute) of Argon is introduced and a pressure of 5 millitorr is established. The power supplies are started with a 150 watt set point and is allowed to establish plasma and stabilize for approximately one half minute after which a shutter covering the target face is opened and a timer started.

At the end of the required time period the power supply, argon flow, and pressure controllers are shut off, the rotation is stopped and the platter is withdrawn into the LL chamber. The isolation valve is closed. After the LL chamber is vented with nitrogen gas, the samples are removed from the Denton 20LL.

Base pressure of the system is approximately 5×10⁻⁷ torr (or lower) before and after deposition.

A 4 mm (length of cross section) by approximately 6 mm sample is submerged in liquid nitrogen for at least 20 sec. At the same time an unused single-edged razor blade held in pliers is submerged in liquid nitrogen. Immediately on removal from the liquid nitrogen, the razor is chopped down onto the side of the film using a guillotine motion as the film is placed on a fresh sheet of glassine over a self-healing cutting mat. This guillotine motion initiates a cross sectioning which is a cross between cryo-cutting and cryo-fracturing and is material dependent.

Once the cross sectioned sample warms to room temperature, the cross section is trimmed to a height of approximately 1 mm using a room temperature single-edged razor blade. This cross section is then mounted on a sample mount (5 mm (w)×7 mm (1)) using Duco brand cement, and coated with 1 nanometer (“nm”) of Osmium (using plasma reaction of OsO4) to enable higher resolution by the SEM technique. The material is placed in a Hitachi S5000SP high resolution FE-SEM at 1 keV accelerating voltage.

The polyimide/molybdenum interface of this prophetic example is expected to have good adhesion (no failure).

### Comparative Example 1

Molybdenum Layer (Approximately 500 nm)+Block Co-Polymer Polyimide (PMDA:ODA) 0.3 (PMDA:PPD) 0.7,

The same procedure as described in Example 1 was followed, except that nanosilica was not added to the formulation.

The formulation was filtered through 45 micron filter media. Approximately 25 grams of material was separated into a small container for the subsequent reaction with 6 wt % PMDA solution to increase the molecular weight of the prepolymer. The final viscosity was approximately 1000-1200 poise.

The same procedure as described in Example 1 for examination by scanning electron microscopy was followed. A minimum of four successful cross sections were examined over the length (4 mm) of the cross section looking for differences in morphology at the polyimide/Mo interface.

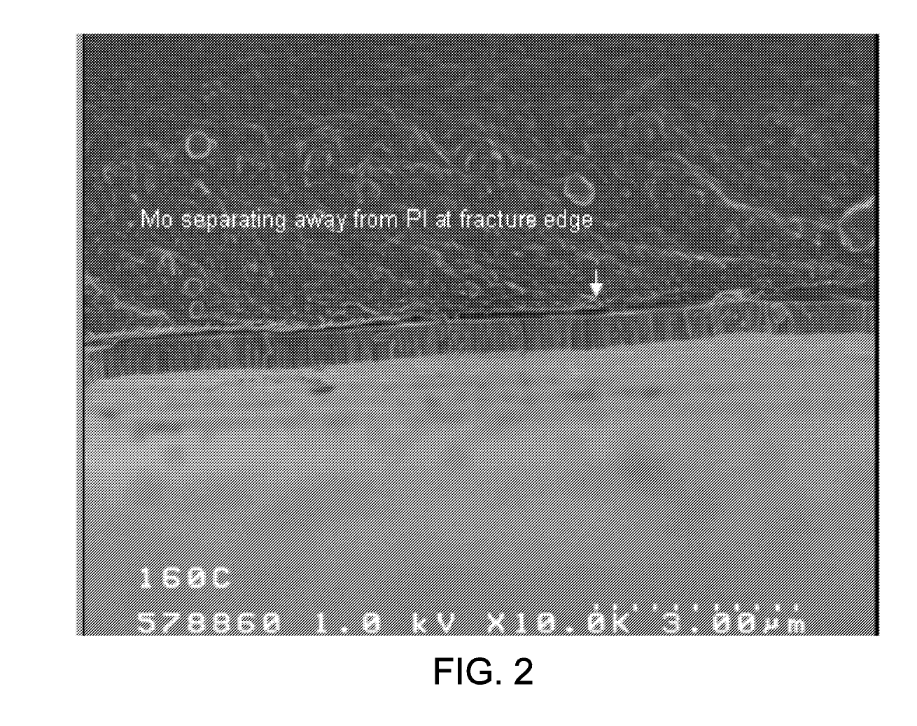

A representative SEM image is illustrated in FIG. 2, where an approximately 500 nm Molybdenum layer is shown. The image showed failure at the polyimide-molybdenum interface.

Note that not all of the activities described above in the general description or the examples are required, that a portion of a specific activity may not be required, and that further activities may be performed in addition to those described. Still further, the order in which each of the activities are listed are not necessarily the order in which they are performed. After reading this specification, skilled artisans will be capable of determining what activities can be used for their specific needs or desires.

In the foregoing specification, the invention has been described with reference to specific embodiments. However, one of ordinary skill in the art appreciates that various modifications and changes can be made without departing from the scope of the invention as set forth in the claims below. All features disclosed in this specification may be replaced by alternative features serving the same, equivalent or similar purpose. Accordingly, the specification and figures are to be regarded in an illustrative rather than a restrictive sense and all such modifications are intended to be included within the scope of the invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims.

What is claimed is:

1. An assembly comprising:
A) a polyimide film comprising:
a) a polyimide in an amount from 40 to 95 weight percent of the polyimide film, the polyimide being derived from:
i) at least one aromatic dianhydride component, said aromatic dianhydride component being a member of the group consisting of rigid rod dianhydride, non-rigid rod dianhydride and combinations thereof,
ii) at least one aromatic diamine component, said aromatic diamine component being a member of the group consisting of rigid rod diamine, non-rigid rod diamine and combinations thereof,
wherein the mole ratio of dianhydride to diamine is 48-52:52-48 and the ratio of A:B is 20-80:80-20 where A is the mole percent of rigid rod dianhydride and rigid rod diamine, and B is the mole percent of non-rigid rod dianhydride and non-rigid rod diamine; and
b) a filler that:
i) has an average diameter of less than 100 nanometers in all dimensions; and
ii) is present in an amount from 5 to 60 weight percent of the total weight of the polyimide film,
the polyimide film having a thickness from 8 to 150 microns,
B) an electrode supported by said polyimide film.

2. The assembly in accordance with claim 1, further comprising a light absorber layer; the electrode is between the light absorber layer and the polyimide film; and the electrode being in electrical communication with the light absorber layer.

3. The assembly in accordance with claim 2, wherein the light absorber layer is a CIGS/CIS light absorber layer

4. The assembly in accordance with claim 3, wherein the assembly further comprises a plurality of monolithically integrated CIGS/CIS photovoltaic cells.

5. The assembly in accordance with claim 1, wherein the filler has an average diameter less than 60 nm in all dimensions.

6. The assembly in accordance with claim 1, wherein the filler is an inorganic oxide.

7. The assembly in accordance with claim 6, wherein the filler is silicon oxide.

8. The assembly in accordance with claim 1, wherein:
a) the rigid rod type dianhydride is selected from a group consisting of 3,3′,4,4′-biphenyl tetracarboxylic dianhydride (BPDA), pyromellitic dianhydride (PMDA), and mixtures thereof; and
b) the rigid rod type diamine is selected from a group consisting of 1,4-diaminobenzene (PPD), 4,4′-diaminobiphenyl, 2,2′-bis(trifluoromethyl)benzidene (TFMB), 1,5-naphthalenediamine, 1,4-naphthalenediamine, and mixtures thereof.

9. The assembly in accordance with claim 1 wherein the polyimide is a block copolymer

10. The assembly in accordance with claim 9 wherein the polyimide is a block copolymer of ODA and PPD with PMDA and 3,3′,4,4′-biphenyl tetracarboxylic dianhydride (BPDA).

11. The assembly in accordance with claim 9 wherein the block copolymer comprises:
i. from 10 to 40 mole % blocks of PMDA and PPD; and
ii. from 60 to 90 mole % blocks of PMDA and ODA.

12. The assembly in accordance with claim 1, wherein the polyimide film comprises a coupling agent, a dispersant or a combination thereof.

13. The assembly in accordance with claim 1, wherein the filler is an inorganic oxide, and the polyimide film has: (i) a Tg greater than 300° C., and (ii) a dielectric strength greater than 500 volts per 25.4 microns,

14. The assembly in accordance with claim 1, wherein the polyimide film comprises two or more layers.

15. The assembly in accordance with claim 1, wherein the polyimide film is reinforced with a thermally stable, inorganic: fabric, paper, sheet, scrim or a combination thereof.
